(19) United States
(12) Patent Application Publication
(10) Pub. No.: US 2009/0093126 A1
(43) Pub. Date: Apr. 9, 2009

(54) METHOD OF AND AN APPARATUS FOR PROCESSING A SUBSTRATE

(75) Inventor: Philippe Garnier, Waffingers Falls, NY (US)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/066,701

(22) PCT Filed: Sep. 8, 2006
(86) PCT No.: PCT/IB06/53180

§ 371 Date: Dec. 18, 2008

(30) Foreign Application Priority Data
Sep. 13, 2005 (EP) 05300746.4

(51) Int. Cl. H01L 21/306

(52) U.S. Cl. 438/745; 156/345.23; 257/E21.219

(57) ABSTRACT

A method of processing a semiconductor substrate (3) comprises spinning the semiconductor substrate (3) while dispensing a reactive etching agent (7) onto a first surface of the spinning substrate (3) to etch a first region (8) of the surface (3). Simultaneously, a neutralising agent (9) is dispensed onto the first surface to neutralise etching agent (9) that has flowed away from the first region (8) of the surface (3), thereby substantially preventing processing of another region (10) of the first surface located nearer an edge of the substrate (3) than is the first region (8). The processing may be etching.

The present invention relates to a method of and an apparatus for etching a substrate, and in particular but not exclusively a semiconductor substrate.

It is known to use chemical etching to enhance the uniformity of films deposited on semiconductor wafers. In the August 2003 edition of www.solid-state.com pages 43 to 46 there is described a technique for correcting high dense plasma (HDP) uniformity problems, edge to centre, using a wet etcher. This technique enhances the Chemical Mechanical polishing (CMP) process for shallow trench integration (STI).

There are however, a number of drawbacks with this technique. For example, the technique relates only to edge to centre uniformity centre, and may perform only a limited number of edge to centre etch profiles. Furthermore, the wet etch of this technique is difficult to control.

US 2005/0020077 describes a system for cleaning the bevel edge of a semiconductor substrate while simultaneously providing protection layer over the production surface of the substrate. The protection layer may include a thin layer of de-ionized water applied to the centre of the substrate while the substrate is rotated.

Embodiments of the present invention aim to at least alleviate some of the above described problems.

According to the present invention there is provided a method of processing a substrate, the method comprising: spinning the substrate, dispensing a reactive agent onto a first surface of the spinning substrate to process a first region of the first surface, and simultaneously dispensing a neutralising agent onto the first surface so as to neutralise the reactive agent that has flowed away from the first region of the surface to substantially prevent processing of another region of the first surface located nearer an edge of the substrate than is the first region.

According to the invention there is also provided an apparatus for processing a substrate, the apparatus comprising:

a support for rotatably supporting the substrate, a first dispenser for dispensing a reactive agent onto a first surface of the rotating substrate to process a first region of the surface,

a second dispenser for simultaneously dispensing a neutralising agent onto the first surface to neutralise the reactive agent that has flowed away from the first region of the surface, thereby substantially preventing processing of another region of the first surface located nearer an edge of the substrate than is the first region.

In a preferred embodiment a first dispensing arm is used to dispense the reactive agent and the first dispensing arm is moved from one dispensing position to another relative to the spinning substrate to process a different one of a plurality of regions to be processed.

A second dispensing arm is used to dispense the neutralising agent and the second dispensing arm is moved from one dispensing position to another relative to the spinning substrate to neutralise the reactive agent that has flowed away from a different one of the plurality of regions to be processed.

Preferably the substrate is a semiconductor surface.

An embodiment of the invention will now be described by way of example only with reference to the accompanying drawing in which:

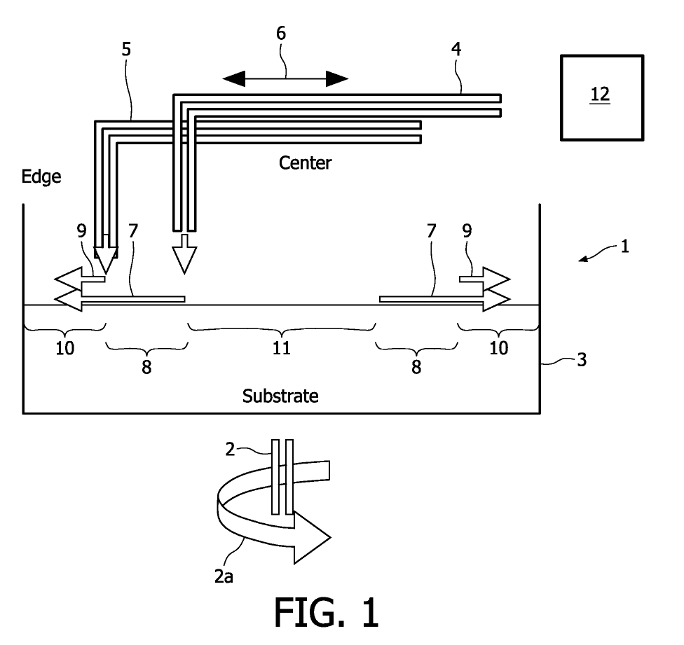

FIG. 1 is a schematic diagram of a system embodying the present invention;

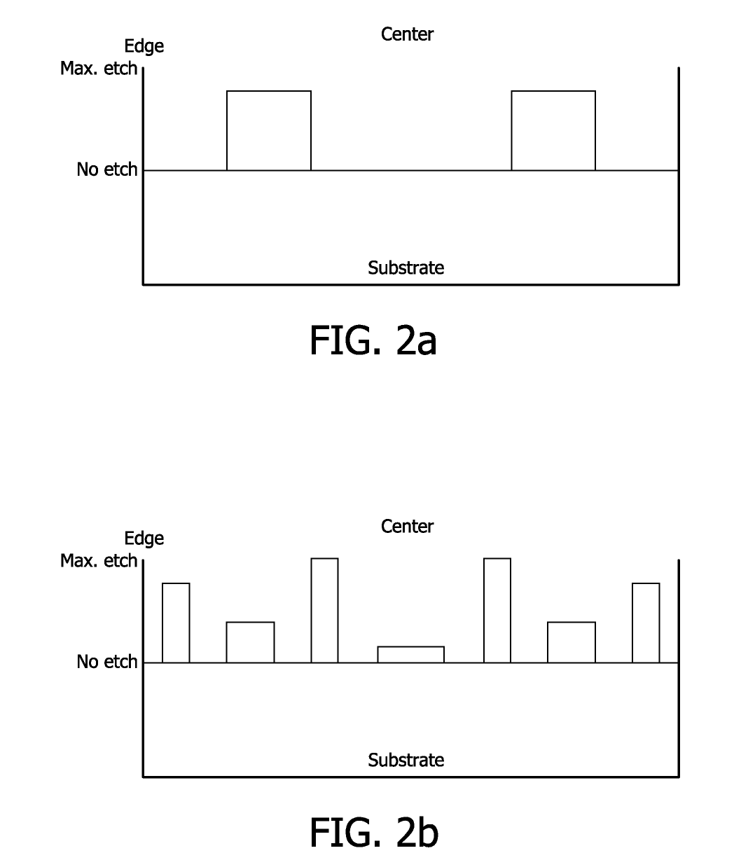

FIGS. 2a and 2b illustrate etching profiles.

Referring to FIG. 1 of the drawings, wet spin etch apparatus 1 comprises a rotatable support 2 for supporting semiconductor substrate 3. The support 2 is rotatable about its longitudinal axis such that in use, the substrate 3 spins about this axis as indicated by the arrow 2a. A suitable drive mechanism (not shown) may be used to rotate the support 2.

The apparatus 1 further comprises an etching agent dispensing arm 4 and a neutralising agent dispensing arm 5. In use, both arms 4 and 5 are supported above the spinning substrate 3 by a support (not shown) and are radially movable across the substrate 3 as indicated by arrow 6. The arms may be moved lateral, for example by means of a sliding mechanism, or rotational, for example by a swiveling arm.

The etching agent dispensing arm 4 dispenses a flow of etching agent 7 to wet etch a ring 8 where required on the surface of the substrate 3. Centrifugal forces cause the etching agent to flow outwards towards the edge of the substrate. Simultaneously, the neutralising agent dispensing arm 5 dispenses a flow of neutralising agent 9, which neutralises the etching agent 7 in a neutralised region 10 where no etch is required.

In this example, a central region 11 of the substrate requires no etching and so is not exposed to the flow of etching agent 7 at all. However, the invention may also be applied to cases where the central region does require etching.

By neutralising the flow of etching agent 7 as described above, inner regions of the substrate 3 can be etched while outer regions are left un-etched. A controller 12 controls the position and movement of the arms 4 and 5 as they dispense their respective agents enabling complicated etchings having multiple etched rings to be obtained, examples of which are illustrated in FIGS. 2a and 2b.

The etchings illustrated in FIGS. 2a and 2b have relatively straight discontinuous profiles but the technique can be used to obtain etches having a smooth profile and etches having various types of slopes.

In one embodiment of the invention, warm HF solution is used as the etching agent 7 and standard cleaning solution NH₄OH/H₂O₂/H₂0 is used as the neutralising agent. Other chemicals suitable for these purposes will be known by those skilled in the art, for example HCl solution may be used as the etching agent 7. Preferably, the standard cleaning solution further comprises a surfactant to prevent salt and particle deposition on the wafer.

In a preferred embodiment a cold liquid, for example, de-ionised water is dispensed on the backside of the substrate to cool the substrate. The etching effect of the etching agent 7 is temperature dependent and using the liquid to control the temperature of the substrate in turn controls the etch profile. For example, a higher etch may be obtained near the substrate centre than near the substrate edge because the temperature of the etching agent is lower near the edge.

The backside cooling liquid may therefore be dispensed using a third moveable dispensing arm.

The technique described above may be applied widely. Nowadays, major wafer uniformity problems are radial/ring problems because films are mainly grown or deposited on rotating single wafers, resulting in a central symmetry. The described technique may substitute part of existing CMP applications if correct and selective chemistries are used.

The technique may be used in Advanced Process Control. A wafer's uniformity may be measured by ellipsometry and a wet etch recipe automatically defined to correct a non-uniform profile. Etch slopes, where to etch, surface to etch is then automatically defined in a recipe. Wafers may be etched with the most accurate wet etch recipe, on a wafer by wafer basis.

The technique may be used in wafer characterization processes. N dose in DPN films is very important for electrical parameter reasons and is measured by X-ray photoelectron spectroscopy (XPS) measurements. To obtain an in depth N dose profile, DPN wafers need to be repeatedly etched and the N dose measured after each etch. This is a time consuming process. The technique may be applied to set a profile at the same time and if the N dose is laterally uniform only one etch with the desired profile is required and one XPS multi site measurement required. The same approach can be performed on all homogeneous surfaces and in depth inhomogeneous film.

The technique may be applied in Wafer de-processing in a selected area (one or more rings) on a wafer with several etch depths on the same wafer.

Although the preferred embodiment relates to the etching of a semi conductor substrate, it will be appreciated that embodiments of the invention may be used to etch other types of substrate, for example, glass panels.

Though in the description above only etching processes have been described, the invention can also be used for other processing of a substrate, using other reactive agents.

Having thus described the present invention by reference to preferred embodiments it is to be well understood that the embodiments in question are exemplary only and that modifications and variations such as will occur to those possessed of appropriate knowledge and skills may be made without departure from the spirit and scope of the invention as set forth in the appended claims and equivalents thereof. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements.

The various elements of the various embodiments may be combined without departing from the scope of the invention.

1. A method of processing a substrate, the method comprising: spinning the substrate, dispensing a reactive agent onto a first surface of the spinning substrate to process a first region of the first surface, and simultaneously dispensing a neutralising agent onto the first surface so as to neutralise the reactive agent that has flowed away from the first region of the surface to substantially prevent processing of another region of the first surface located nearer an edge of the substrate than is the first region.

2. A method according to claim 1, further comprising, dispensing the reactive agent onto the first surface of the spinning substrate to process in succession a plurality of regions of the surface to be processed, and when the reactive agent is dispensed to process each region to be processed, simultaneously dispensing the neutralising agent onto the first surface to neutralise the reactive agent that has flowed away from a region to be processed, thereby substantially preventing processing of a region of the surface located nearer an edge of the substrate than is the given region to be processed.

3. A method according to claim 1, the method comprising using a first dispensing arm to dispense the reactive agent and using a second dispensing arm to dispense the neutralising agent.

4. A method according to claim 2, the method comprising using a first dispensing arm to dispense the reactive agent and wherein the first dispensing arm is moved from one dispensing position to another relative to the spinning substrate and when in each dispensing position processes a different one of the plurality of regions to be processed.

5. A method according to claim 4, the method comprising using a second dispensing arm to dispense the neutralising agent and wherein the second dispensing arm is moved from one dispensing position to another relative to the spinning substrate and when in each dispensing position neutralises the reactive agent that has flowed away from a different one of the processed regions.

6. A method according to claim 1 wherein the reactive agent is warm.

7. A method according to claim 1 wherein the reactive agent is acidic.

8. A method according to claim 7 wherein the reactive agent comprises HF solution.

9. A method according to claim 1 wherein the neutralising agent is alkaline

10. A method according to claim 9 wherein the neutralising agent comprises NH₄OH/H₂O₂/H₂0 solution.

11. A method according to claim 1 wherein the substrate is a semiconductor substrate.

12. A method according to claim 1 wherein the processing is etching and the reactive agent is an etching agent.

13. An apparatus for processing a substrate, the apparatus comprising:
a support for rotatably supporting the substrate, a first dispenser for dispensing a reactive agent onto a first surface of the rotating substrate to process a first region of the surface,
a second dispenser for simultaneously dispensing a neutralising agent onto the first surface to neutralise the reactive agent that has flowed away from the first region of the surface, thereby substantially preventing processing of another region of the first surface located nearer an edge of the substrate than is the first region.

14. An apparatus according to claim 13 wherein the first dispenser comprises a first dispensing arm for dispensing the reactive agent and the second dispenser comprises a second dispensing arm for dispensing the neutralising agent.

15. An apparatus according to claim 14 wherein the first dispensing arm and the second dispensing arm are moveable relative to the substrate such that the first dispensing arm can be moved to dispense the reactive agent to process a plurality of regions on the first surface and each time a region is processed the second dispensing arm positioned to dispense neutralising agent to neutralise the reactive agent that has flowed away from the region being processed, thereby substantially preventing processing of another region of the first surface located nearer an edge of the substrate than is the region being processed.
